(19) United States
(12) Patent Application Publication
(10) Pub. No.: US 2006/0131708 A1
(43) Pub. Date: Jun. 22, 2006

(54) Packaged electronic devices, and method for making same

(76) Inventors: Kee Yean Ng, Prai Penang (MY); Hui Peng Koay, Penang (MY); Yew Cheong Kuan, Penang (MY)

Correspondence Address: AGILENT TECHNOLOGIES, INC.;INTELLECTUAL PROPERTY ADMINISTRATION, LEGAL DEPT., P.O. BOX 7599, M/S DL429, LOVELAND, CO, 80537-0599, US

(21) Appl. No.: 11/014,646

(22) Filed: Dec. 16, 2004

(51) Int. Cl. H01L 23/02

(52) U.S. Cl. 257/678

(57) ABSTRACT

In one embodiment, an electronic device is packaged by electrically connecting the electronic device to an electrical contact on a substrate; applying a binding agent to bind the electronic device to the electrical contact; and then removing at least a portion of the substrate to expose the electrical contact as a package contact. The substrate may take various forms and may be removed in a variety of ways, which include chemical and mechanical processes. In some embodiments, the electrical contact may have a non-uniform thickness and may be provided with a reinforcement rib or a slotted profile.

### BACKGROUND

Light emitting diodes (LEDs) are used in many mobile devices (e.g., mobile phones, personal digital assistants (PDAs), and digital cameras). Often, LEDs are used to backlight liquid crystal displays (LCDs) and keypads, or to provide status indications.

FIG. 12 illustrates a chip-type LED package 1200 comprising a printed circuit board (PCB) substrate 1202. The substrate 1202 is provided with pairs of electrical contacts 1204/1206, 1208/1210 on opposite surfaces thereof. One pair of contacts 1204/1206 is coupled to an LED 1212 (e.g., via conductive adhesive 1214 and wire bond 1216. The other pair of contacts 1208, 1210 serve as package contacts, and is coupled to the first pair of contacts 1204, 1206 by means of a pair of vias 1218, 1220. A transparent encapsulant (e.g., a transparent epoxy 1222) serves to protect the LED 1212 and wire bond 1216 from damage.

The thickness (or height) of the LED package 1200 is determined by the combined thicknesses of the substrate 1202, encapsulant 1222 and contacts 1204/1206, 1208/1210, although the substrate 1202 and encapsulant 1222 are clearly the most significant contributors to the package's thickness. Often, the thinness of the substrate 1202 is limited by handling considerations during processing (e.g., the substrate 1202 cannot be so thin that it is easily broken during handling and processing). The thinness of the encapsulant 1222 is limited by the height of the LED 1212 and the wire bond 1216.

Although currently available LED packages are as thin as 0.35 mm (millimeters), there is continuing pressure to reduce this thickness as LED packages are employed in smaller and smaller mobile devices. There is also pressure to reduce the thickness of other types of electronic device packages (e.g., laser diode and microprocessor packages).

### SUMMARY OF THE INVENTION

In one embodiment, a method for packaging an electronic device comprises electrically connecting an electronic device to an electrical contact on a substrate; applying a binding agent to bind the electronic device to the electrical contact; and then removing at least a portion of the substrate to expose the electrical contact as a package contact.

In another embodiment, a packaged electronic device comprises an electronic device; an electrical contact that is electrically connected to the electronic device; and a binding agent binding the electronic device to the electrical contact.

In yet another embodiment, a packaged electronic device comprises an electronic device; an electrical contact that is formed on a substrate and electrically connected to the electronic device; and a binding agent binding the electronic device to the electrical contact. At least a portion of the substrate is removed to expose the electrical contact as a package contact.

Other embodiments are also disclosed.

### BRIEF DESCRIPTION OF THE DRAWINGS

Illustrative embodiments of the invention are illustrated in the drawings, in which:

FIG. 1 illustrates an exemplary method for packaging an electronic device;

FIGS. 2A, 2B, 2C & 2D illustrate an exemplary application of the FIG. 1 method;

FIG. 3 illustrates a variation of the packaged device shown in FIG. 2D, wherein a portion of a removed substrate remains adhered to the package;

FIG. 4 illustrates another variation of the packaged device shown in FIG. 2D, wherein a portion of the binding agent that binds an electronic device to one or more electrical contacts has been removed along with the substrate on which the electrical contacts were originally formed;

FIG. 5 illustrates a packaged electronic device having electrical contacts with reinforcing ribs;

FIG. 6 illustrates a packaged electronic device having electrical contacts with slotted profiles;

FIG. 7 illustrates a packaged electronic device having an electrical contact forming a reflector cup;

FIG. 8 illustrates a packaged flip chip;

FIGS. 9 & 10 illustrate alternate versions of the devices shown in FIGS. 2D & 7;

FIG. 11 illustrates an alternate wire bond placement for the device shown in FIG. 2D; and

FIG. 12 illustrates a packaged device comprising a package substrate.

### DETAILED DESCRIPTION OF AN EMBODIMENT

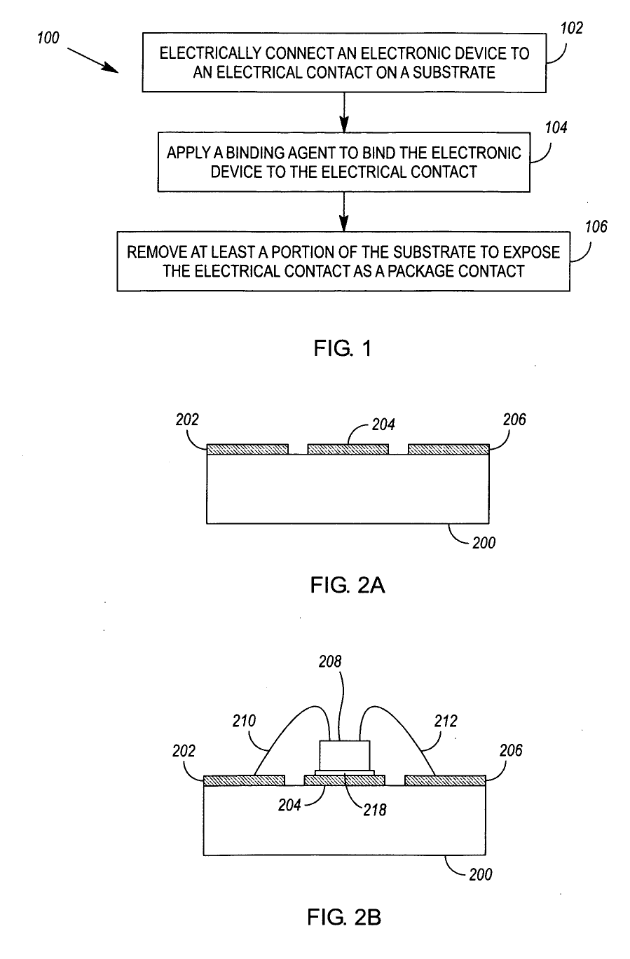

FIG. 1 illustrates an exemplary method 100 for packaging an electronic device. In accordance with the method 100, an electronic device is electrically connected 102 to an electrical contact on a substrate. A binding agent is then applied 104 to bind the electronic device to the electrical contact. Thereafter, at least a portion of the substrate is removed 106 to expose the electrical contact as a package contact.

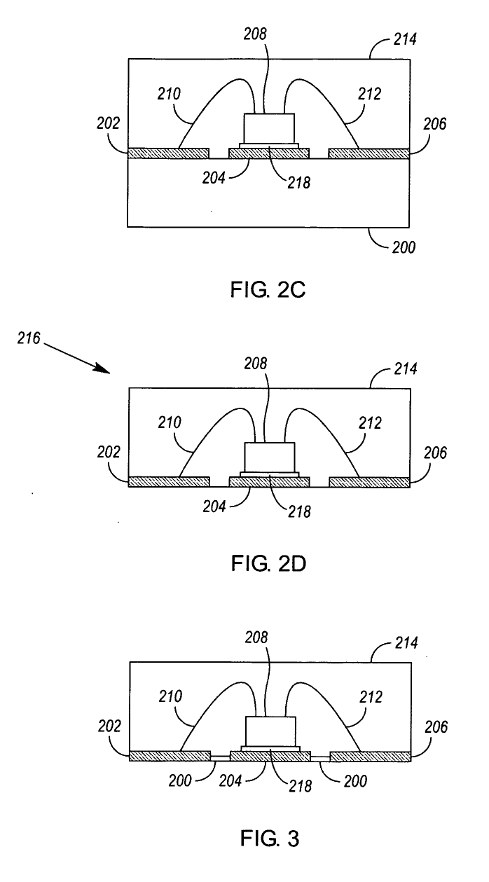

One exemplary application of the method 100 is illustrated in FIGS. 2A-2D. By way of example, a substrate 200 is shown to have three electrical contacts 202, 204, 206 (e.g., traces or pads) formed thereon (see FIG. 2A). An electronic device 208 may be mounted on one of the electrical contacts 204 (e.g., via an adhesive 218), and wire bonds 210, 212 may be used to couple the electronic device 208 to the other electrical contacts 202, 206 (see FIG. 2B). A binding agent 214 may then be applied to bind the electronic device 208 to the electrical contacts 202-206 (see FIG. 2C). As shown, the binding agent 214 may also bind the wire bonds 210, 212, and may even encapsulate the electronic device 208, the wire bonds 210, 212, and part or all of the electrical contacts 202-206. After application of the binding agent 214, the substrate 200 is removed to expose the electrical contacts 202-206 as package contacts on a thin-packaged electronic device 216 (see FIG. 2D).

The substrate 200 may take any of a number of forms, including organic and inorganic forms. For example, the substrate 200 can be a semiconductor substrate (e.g., silicon, or gallium arsenide), a laminate substrate (e.g., glass epoxy laminate, or phenolic laminate), a plastic composite substrate (e.g., Amodel® polyphthalamide, polycarbonate, polystyrene, or acrylonitrile-butadiene-styrene (ABS)), a polymer substrate or a metallic substrate (e.g., copper or steel). Unlike a substrate that is to form part of a package, and which is desirable to be thin to help minimize total package thickness, the substrate 200 may be of any thickness that gives it sufficient rigidity for the processes in which it will be handled or manipulated. That is, the substrate 200 need not be so thin that it is fragile to handle.

Depending on the composition of the substrate 200, it may be removed from the binding agent 214, electronic device 208 and electrical contacts 202-206 by a variety of means, including chemical and/or mechanical means. For example, the substrate 200 can be removed via a wet or dry chemical etching process. Depending on the composition of the substrate 200, a wet chemical etching process may employ an acidic, an alkaline, or even a neutral etching solution. Alternately, the substrate 200 could be removed via a plasma etching process. Mechanical means for removing the substrate 200 include lapping (i.e., removing the substrate 200 by abrasion using a hard surface or hard particles). Yet alternately, the substrate 200 could be removed via application of heat or radiation such as from a laser.

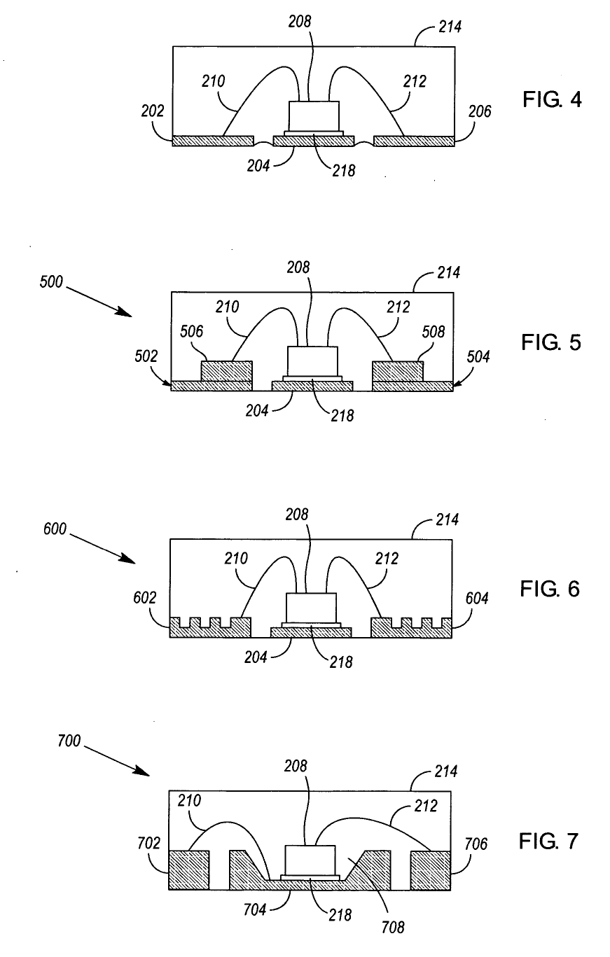

In some cases, all of the substrate 200 may be removed, as shown in FIG. 2D. In other cases, the electrical contacts 202-206 may be partially embedded in the substrate 200, and portions of the substrate 200 may remain adhered to the binding agent 214 after the contacts 202-206 have been exposed (see FIG. 3). In yet other cases, a substrate removal means such as etching may result in partial removal of the binding agent 214 in addition to removal of the substrate 200 (see FIG. 4). However, it is preferable that the binding agent 214 be impervious to (or at least resistant to) the means that is used to remove the substrate 200.

The electrical contacts 202-206 may be formed on the substrate 200 using any of a number of methods, including electroless plating, electrolytic plating, a cladding process, a plate and etch process, sputtering, or evaporation. In some cases, the contacts 202-206 may comprise stacks of metal layers, such as one or more copper, nickel, gold, silver, titanium, platinum, germanium, tin and/or tungsten layers. For example, contacts formed of copper, nickel and gold layers, or copper, nickel and silver layers, are useful. Alternately, two or more metals may be mixed and then deposited as a single contact layer.

The electrical contacts 202-206 may be of uniform or varying thickness. For many applications, contact thicknesses between 1 and 100 microns are useful. FIGS. 5-7 illustrate a variety of thin-packaged electronic devices 500, 600, 700 having electrical contacts of non-uniform thickness. In FIG. 5, a portion of electrical contacts 502, 504 are built up with reinforcing layers 506, 508 to form reinforcing ribs that provide additional strength and rigidity to the thin-packaged device 500. If, however, the height of the contacts 502, 504 is less than the height of the electronic device 208, then the greater thickness of the contacts 502, 504 provides no additional thickness to the packaged device 500.

In FIG. 6, the slotted or ribbed profiles of its electrical contacts 602, 604 can assist in adhering the contacts 602, 604 to the binding agent 214, thereby reducing the likelihood that the contacts 602, 604 will peel or separate from the binding agent 214. It is noted that the non-uniform thickness of the contacts 502, 504 shown in FIG. 5 can also assist in adhering the contacts 502, 504 to the binding agent 214.

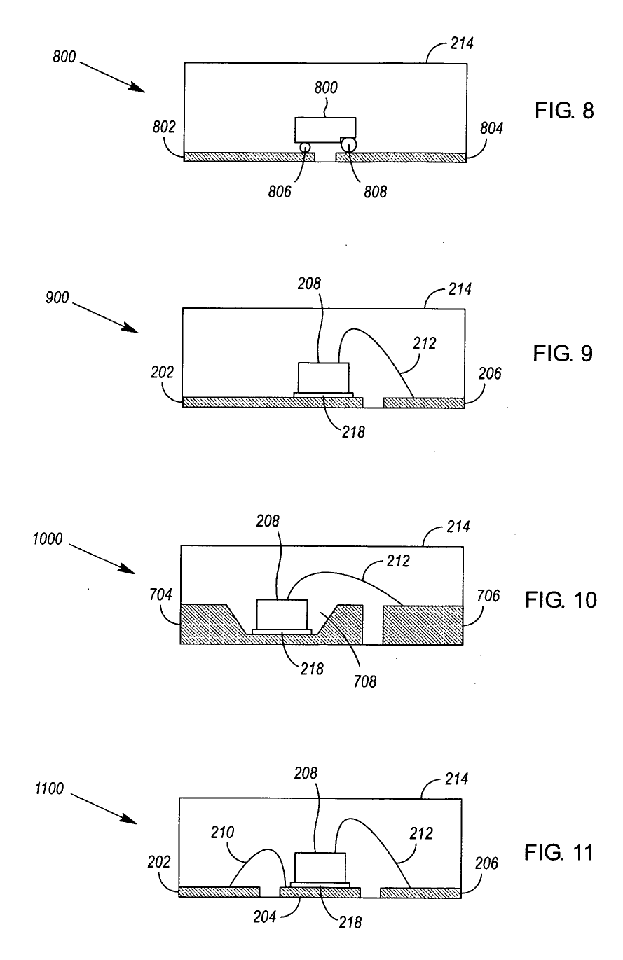

In FIG. 7, the electronic device 208 is a light emitting diode (LED), and one of the electrical contacts 702, 704, 706 is provided with a depression 708 that serves as a reflector cup for reflecting light emitted by the LED.

In alternate embodiments of thin-packaged electronic devices, the profiles of electrical contacts may take other forms.

Referring again to FIGS. 2A-2D, one should note that the electrical contacts 202-206 may alternately provide electrical connection or heatsink functionality. When mounting the electronic device 208 to one of the contacts 204, the device 208 may be mounted via solder, eutectic or conductive adhesive 218. Alternately, the electronic device 208 could be mounted directly to the substrate 200 via solder, eutectic, conductive adhesive, or non-conductive adhesive.

The electronic device 208 may take the form of any one or more semiconductor devices, including that of an LED, laser diode, photodiode, microprocessor, resistor, capacitor or inductor. If the device 208 is an LED, laser diode or photodiode, the binding agent 214 should have suitable optical properties (e.g., it should be translucent or transparent). In any case, the binding agent 214 may be selected, for example, based on its thermal, insulating and/or structural properties (e.g., its strength or rigidity).

By way of example, the electronic device 208 shown in FIG. 2D is an LED die. FIG. 8 illustrates the mounting of a flip chip 800 to a pair of electrical contacts 802, 804. A flip chip is useful in that no bond wires are required to connect it to its electrical contacts 802, 804. Rather, solder bumps, plated bumps, gold stump bumps, conductive adhesive bumps or other bumps 806, 808 are merely reflowed to couple the flip chip 800 to its contacts 802, 804. In contrast to the device 208, the device 800 may provide for a reduction in the thickness of binding agent 214 (e.g., because there is no need to encapsulate wire bonds 210, 212).

The devices 900, 1000 shown in FIGS. 9 & 10 illustrate single wire bond 212 versions of the devices 216, 700 shown in FIGS. 2D & 7, while the device 1100 shown in FIG. 11 shows an alternate placement of the wire bond 210. Depending on the type of device being packaged, as well as its application, a device may be provided with more or fewer electrical contacts, and various numbers and placements of wire bonds.

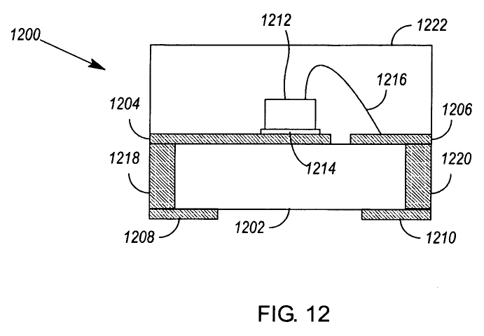

It is noted that the thin-packaged electronic devices described above do not contain package substrates 1202, substrate mounting contacts 1208, 1210, or device-to-package contact connections 1218, 1220 (as shown in the package 1200 in FIG. 12). Instead, the electronic device 208 is connected to package contacts 202-206 in the absence of an intermediary substrate 1200.

As a result of the foregoing electronic devices not including a package substrate 1200, they may often be made thinner than other packaged electronic devices. For instance, where the electronic device 208 is an LED die, a package thickness of less than 0.3 mm can be achieved. A further benefit may be a reduction in thermal path, allowing a more efficient transfer of heat away from the electronic device 208.

What is claimed is:

1. A method for packaging an electronic device, comprising:
electrically connecting an electronic device to an electrical contact on a substrate;
applying a binding agent to bind the electronic device to the electrical contact; and
removing at least a portion of the substrate to expose the electrical contact as a package contact.

2. The method of claim 1, wherein the electronic device is a light emitting diode (LED).

3. The method of claim 1, wherein the binding agent is transparent.

4. The method of claim 1, further comprising, forming the electrical contact on the substrate, the electrical contact being formed to have a non-uniform thickness.

5. The method of claim 4, wherein the electrical contact is formed to provide a reflector cup, the method further comprising mounting the electronic device in the reflector cup.

6. The method of claim 4, wherein the electrical contact is formed to have a slotted surface to which the binding agent is applied.

7. The method of claim 1, wherein the substrate is selected from the group consisting of: semiconductor, polymer, plastic composite and metal.

8. The method of claim 1, wherein the substrate is at least partly removed by a mechanical process.

9. The method of claim 1, wherein the substrate is at least partly removed by a chemical process.

10. The method of claim 9, wherein the chemical process comprises chemical etching.

11. A packaged electronic device, comprising:
an electronic device;
an electrical contact, electrically connected to the electronic device; and
a binding agent binding the electronic device to the electrical contact, wherein the binding agent provides a package for the electronic device, and wherein the electrical contact is embedded in and exposed on a surface of the binding agent.

12. The device of claim 11, wherein the electrical contact has a non-uniform profile.

13. The device of claim 11, wherein a surface of the electrical contact bound by the binding agent is slotted.

14. The device of claim 11, wherein a surface of the electrical contact bound by the binding agent comprises a reinforcement rib.

15. The device of claim 11, wherein the electrical contact comprises copper, nickel, gold, silver, titanium, platinum, germanium, tin, tungsten or a combination thereof.

16. The device of claim 11, wherein the electrical contact forms a reflector cup about the electronic device.

17. A packaged electronic device, comprising:
an electronic device;
an electrical contact formed on a substrate, the electrical contact being electrically connected to the electronic device; and
a binding agent binding the electronic device to the electrical contact, wherein at least a portion of the substrate has been removed to expose the electrical contact as a package contact.

18. The device of claim 17, wherein the electronic device is a light emitting diode (LED).

19. The device of claim 17, wherein the electronic device is a flip chip.

20. The device of claim 17, wherein the binding agent is transparent.
